(19) United States
(12) Patent Application Publication
(10) Pub. No.: US 2008/0280130 A1
(43) Pub. Date: Nov. 13, 2008

(54) Component, an apparatus and a method for the manufacture of a layer system

(76) Inventors: Wolfram Beele, Ratingen (DE); Richard K. Schmid, Gerlikon (CH)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 11/706,578

(22) Filed: Feb. 14, 2007

(30) Foreign Application Priority Data
Feb. 16, 2006 (EP) 06405071.9

(51) Int. Cl. C23C 14/34; B32B 5/00

(52) U.S. Cl. 428/332; 204/298.14; 204/192.15

(57) ABSTRACT

The invention relates to a component and also an associated coating apparatus and method, including a base body (1), in particular a metallic base body, which includes at least one nickel and/or cobalt base alloy, and also a layer system arranged directly on the base body (1). The layer system includes a bond promoting layer (2) and also a thermally insulating layer arranged on the bond promoting layer, including a TGO layer (3), in particular a slow growing aluminium oxide layer (4) and/or chrome oxide layer as well as at least one oxide ceramic layer which is arranged directly on the TGO layer and a cover layer (5) of an A₂E₂O₇ pyrochlorine arranged on the oxide ceramic layer (4). A preferably includes a lanthanide, in particular gadolinium and E preferably includes zirconium, and also in particular lanthanum zirconate, and/or a perovskite phase. The layer thicknesses of the oxide ceramic layer (4) and the cover layer (5) together amount to between 50 μm and 2 mm, in particular together amount to between 100 μm and 500 μm.

This application claims the priority of European Patent Application No. 06405071.9, filed Feb. 16, 2006, the disclosure of which is incorporated herein by reference.

The invention relates to a method for the manufacture of a layer system, which includes, in particular, multiple layer thermally insulating layers for components subjected to high temperatures, such as, for example, gas turbine blades, and also to an associated apparatus, wherein new layer materials and layer systems are used which have a reduced thermal conductivity.

The invention particularly relates to a component, a coating apparatus and a method for the coating of a base body with a layer system. The method preferably includes a PVD method, in particular a HS-PVD method, which is also known by the term reactive gas sputtering.

A layer system is disclosed in the prior art in accordance with EP 1591550, which includes a substrate, a bond promoting layer, a TGO layer, an yttrium (partially) stabilised zirconium oxide layer and also a cover layer made of a zirconium oxide based ceramic material and also at least one element from the group La, Ce, Pr, Nd, Sm, Eu, Gd, Tb, Dy, Ho, Er, Tm, Yb, Lu, Sc, In, Y, Mo, C and also oxides of the rare earths.

Different research projects have shown that the materials used for thermal conductivity reduction in accordance with the disclosures EPO848077, U.S. Pat. No. 6,231,991, EP1577499, U.S. Pat. No. 6,110,604, U.S. Pat. No. 6,376,015 have, as a rule, to be applied as a multi-layer in order to ensure adequate bond promotion.

Furthermore, it was found in U.S. Pat. No. 6,110,604 that additional intermediate layers have a favourable heat reflection behaviour. These intermediate layers have in part accumulations of atomic lattice vacancies, by which hollow cavities form.

A heat insulating layer system with an intermetallic bond promotion cover is know from U.S. Pat. No. 5,238,752. The heat insulating layer system is applied to a metallic base body, in particular to a Ni or Co superalloy for an aircraft engine blade. An intermetallic bond promoting layer, in particular made of a nickel aluminide or of a platinum aluminide is applied directly onto this metallic base body. A thin ceramic layer of aluminium oxide joins this bond promoting layer, onto which the actual heat insulating layer, in particular of zirconium oxide stabilised with yttrium oxide, is applied. This ceramic heat insulating layer of zirconium oxide has a rod-like structure, wherein the rod-like columns are directed substantially perpendicular to the surface of the base body. In this way an improvement in the ability to withstand thermal cycling can be guaranteed. The heat insulating layer is deposited onto the base body by means of an electron beam PVD method (physical vapour deposition), wherein zirconium and yttrium oxide are vaporised out of a metal oxide body with an electron beam cannon. The method is carried out in an apparatus in which the base body is preheated to a temperature of approximately 950° to 1000° C. The base body is rotated in the beam of metallic oxide during the coating process. Details of the columnar grain structure and its characteristics can not be deduced from U.S. Pat. No. 5,238,752, or rather can not be specifically established using the method described there. The electron beam PVD method for the manufacture of ceramic coatings with a columnar grain structure is further described in U.S. Pat. No. 5,087,477 and U.S. Pat. No. 5,262,245, wherein the deposition of zirconium oxide on a base body takes place in an oxygen enriched vacuum atmosphere.

Further methods and examples for the application of a heat insulating layer system on a gas turbine blade are described in U.S. Pat. No. 5,514,482 and in U.S. Pat. No. 4,405,659. According to U.S. Pat. No. 4,405,659, it should be possible, using the electron beam PVD method, to apply a heat insulating layer of zirconium oxide partially stabilised with yttrium oxide, which displays a layer thickness of approximately 125 μm and has a columnar structure. The mean cross-sectional area of a column should amount to the order of magnitude of 6.5 μm². However, the electron beam PVD method is associated with considerable process complications which are caused, among other things, by the control of the melt pool, by the requirement for compulsory operation in the high vacuum range and, not least by the behaviour of the electron beam itself.

The coating of metallic components, in particular gas turbine blades made of a superalloy, by a composite system with an adhesive layer and a heat insulating layer is likewise described in WO 93/18199. The application of the heat insulating layer takes place here using the EB-PVD method and shows all the disadvantages of this, such as considerable procedural complications due to melt pool protocols, high vacuum environment and guidance of the electron beam.

A “method and apparatus for reactive gas sputtering” is disclosed in DD 2 94 511 AS. According to the method described here an inert gas, in particular argon, is fed through a hollow cathode, in the centre of which an anode is arranged, so that an ionisation of the argon atoms takes place. These impinge upon the cathode, whereby cathode material enters the interior of the hollow cathode and is conveyed out of this with the flow of inert gas. The cathode material is a pure metal, to which oxygen is supplied outside the hollow cathode, so that a complete oxidation of the metal, in particular of the zirconium, takes place. The partial pressure of the supplied oxygen is thus of the order of magnitude of 10⁻⁴ Pa. The total dynamic pressure in the environment of the semi-conductor to be coated amounts to approximately 13 Pa to 24 Pa. The deposition rate amounts to approximately 15 nm/min, with the substrate having a temperature of approximately 400° C. The hollow cathode is formed as a cylindrical tube of zirconium with a degree of purity of 99.7%. This deposition rate is not located in a range, which is interesting for industrial use, since the coating of large surfaces is not economic for reasons of the length of time needed for the manufacture of a coating of a single layer.

An alternative formation of the hollow cathode for the achievement of a larger coating surface and a larger coating rate is described in the article “High rated deposition of alumina films by reactive gas flow sputtering” by T. Jung and A. Westphal, in Surface and Coatings Technology, 59, 1993, pages 171 to 176 (DE 42 35 953 A1 corresponds to this). The hollow cathode specified is constructed to be linear in the sense that plates made of zirconium are arranged next to one another in a housing. A flow of inert gas can be fed through between two adjacent plates in each case, so that a plasma of inert gas atoms forms between adjacent plates. The plates can, moreover, have a cooling system, in particular cooling channels. Test bodies made of silicon, stainless steel and glass are coated with the hollow cathode and the strength of the aluminium oxide layer is tested at up to 200° C. The two named articles contain no pronouncements on the structural characteristics of the oxide layers as regards the crystallite size and orientation.

Common to all these developments documented in the above-named disclosures is the fact that the complexity of the process management with regard to the available materials and contamination-free and/or defect-free intermediate layers between the layers increases considerably, since these layers are ideally deposited in a single vacuum chamber one after the other.

For this reason there is a need for a method and for an apparatus which make available the possibility, at an economically viable cost, of depositing the widest possible choice of material combinations in situ.

Furthermore, the coating procedure should be completed in a shorter time, which necessitates the use of a method which permits a higher layer formation rate.

This object leads to the further development of the gas flow PVD technique known from PCT/DE97/02152 for the manufacture of ceramic layers on gas turbine components. A problem, which is associated with the method described there, is the restriction to a single thermally insulating layer. The use of a single thermally insulating layer made of a single material, such as the zirconium oxide partially stabilised with yttrium oxide disclosed in the same document is that the components coated in this manner have an insufficiently reduced thermal conductivity for many uses in the high temperature range. Moreover, when using a single thermally insulating layer, it cannot be precluded that the heat transmission by radiation accounts for a relatively large part of the total heat transfer. In accordance with EP-A-1273680 ceramic materials in particular are translucent with regard to thermal radiation, in particular at high temperatures, which results in the component absorbing too much heat through the radiation during operation, which can not be dissipated by cooling, or only in an insufficient manner. Moreover, for constructional reasons, it is not always possible to cool the substrate part of the component for reasons of construction.

It is the object of the invention to disclose a component, in particular a gas turbine blade, with a thermally insulating layer, which has a high resistance to high variations in thermal stress, which should, in particular, comprise a plurality of layers. A further object of the invention is to disclose an apparatus and also a method for the manufacture of such a component with a corresponding ceramic thermally insulating layer, wherein different layers of the thermally insulating layer can be deposited in a single system using a plurality of sources in an arbitrary order.

A further object of the invention is to provide a cathode arrangement, which includes in particular a layer for the production of a bond promoting layer.

The object is satisfied in that a component is obtained, including a base body, in particular a metallic base body, which includes at least one nickel-based and/or cobalt-based alloy and also a layer system arranged directly on the base body. The layer system includes a bond promoting layer and also a thermally insulating layer arranged on the bond promoting layer. The thermally insulating layer includes a TGO layer (thermally grown oxide layer), in particular a slow growing aluminium oxide layer and/or a chrome oxide layer, which is arranged directly on the TGO layer, and a cover layer made of an A₂E₂O₇ pyrochlorine, wherein A preferably includes an element of the lanthanum series, in particular on gadolinium (Gd) basis and E is preferably zirconium (Zr), and in particular lanthanum zirconate and/or a perovskite phase. Thus at least one substrate is provided as a base body, which is located in a coating chamber, which includes at least one vacuum generating device and also an apparatus for the receipt of a substrate which is to be coated, wherein a source suitable for the manufacture of a plurality of layers and/or a plurality of sources is/are arranged in the coating chamber and/or the sources have means to facilitate the manufacture of a plurality of layers of the thermally insulating coating, through which means the application of a plurality of layers of a thermally insulating coating is made possible in situ in the coating chamber. The component in accordance with the invention, in particular a gas turbine blade, has a base body, a bonding promoting layer, a TGO layer and a ceramic thermally insulating layer arranged thereon, which includes an oxide ceramic layer with a columnar structure with ceramic columns, wherein the ceramic columns are directed substantially normally towards the surface of the base body. A cover layer is applied on the oxide ceramic layer, preferably by means of a reactive gas sputtering method.

The component is manufactured with a coating apparatus for the manufacture of a layer system on a base body, to which end a method for the coating of a base body with a layer system is used, which takes place, in particular, under a vacuum. The process parameters, such as the vacuum pressure, the oxygen partial pressure and the volume flow of the inert gas are selected in such a way that the above-named columnar structure arises. The layer thicknesses of the oxide ceramic layer and of the cover layer together amount to between 50 μm and 2 mm, in particular to between 100 μm and 500 μm. It is further advantageous, particularly with regard to an extension of the life of and of the adhesion of the oxide ceramic layer on the base body, to generate a chemical bond of the oxide ceramic layer to the metallic adhesive layer. This is achieved, for example, by means of a thin layer of an aluminium oxide, in particular Al₂O₃. A layer made of a ternary Al—Zr—O compound or of an Al—O—N compound is likewise suitable as a bond promoting layer. The ternary Al—Zr—O compound, for example AlZrO₃ is preferably suitable for bonding to an oxide ceramic layer, which contains zirconium oxide. In other oxide ceramic layers, which contain magnesium zirconium oxide spinels, other spinels can be used correspondingly. A layer made of aluminium nitride or a compound (mixed layer) of aluminium nitride and aluminium oxide is also suitable.

In an advantageous design of the component, the oxide ceramic layer includes a zirconium oxide layer, in particular a graded zirconium oxide layer and/or contains a stabiliser, especially such as an yttrium oxide, such as Y₂O₃ in particular, and/or a zirconium oxide, such as ZrO₂ in particular, a hafnium oxide, such as HfO₂ in particular, or a mixed oxide of the two components, which is present partially stabilised by means of an yttrium oxide, such as Y₂O₃. The oxide ceramic layer preferably has a metallic ceramic substance, in particular a zirconium oxide such as ZrO₂. This metallic oxide is preferably manufactured with a stabiliser, such as with an yttrium oxide, in particular Y₂O₃, to avoid a phase transformation at high temperatures. The zirconium oxide is preferably charged with a content of 3% by weight to 12% by weight, in particular 8% by weight of yttrium oxide. In a graded zirconium oxide layer, the zirconium oxide is present in different concentrations in local regions. These local regions can correspond to intermediate layers, but can also represent different structures, which coexist in one layer. Graded layers of this kind can serve for the further reduction of the translucence of the zirconium oxide layer for thermal radiation, so that graded layers of this kind make a substantial contribution to the total thermal insulation, i.e. lead to an increase in the thermal insulating effect.

In an advantageous embodiment of the component, the bond promoting layer is formed as a metallic or intermetallic bond promoting layer, which in particular contains a M₁CrAlY alloy, wherein M₁ stands for at least one of the elements iron (Fe), cobalt (Co), nickel (Ni), chrome (Cr), aluminium (Al), yttrium (Y), and/or the bond promoting layer (2) contains at least one of the elements of the rare earths, hafnium (Hf, tantalum (Ta), Silicon (Si) and/or a metal aluminide, wherein the metal aluminide NiAl, CoAl, TiAl, NiCrAl, CoCrAl, and also PtM₂Al, wherein M₂ includes the elements Fe, Ni, Co, Cr, or combinations of these, in particular PtNiAl, PtNiCrAl. A metallic adhesive layer is applied to the base body for a good connection of the ceramic thermally insulating layer to the metallic base body, in particular made of a nickel-based alloy or other alloys suitable for the manufacture of highly thermally stressable components. With respect to the layer thickness, attention is drawn to U.S. Pat. No. 5,238,752, U.S. Pat. No. 4,321,310 and also to U.S. Pat. No. 4,321,311. The metallic adhesive layer preferably consists of an alloy of the type MCrAlY, wherein M stands for one or more of the elements iron, cobalt or nickel, Cr for chrome, Al for aluminium and Y for yttrium or one of the elements of the rare earths. An intermetallic compound is likewise suitable as an adhesive layer, in particular one made of nickel aluminide or platinum aluminide.

In an advantageous embodiment of the component, a first oxide ceramic layer is provided, which advantageously has a thickness in the region from 5 μm to 50 μm and also has a first cover layer which preferably has a thickness in the range from 5 μm to 50 μm. Moreover, at least one further layer sequence of a further oxide ceramic layer and/or a cover layer is provided. The use of a plurality of layer sequences is advantageous for the above-mentioned materials for the reduction of thermal conductivity, since the bond promotion is improved in comparison with one single layer.

In an advantageous embodiment of the component, the oxide ceramic layer has ceramic columns with a column diameter in a region of below 2.5 μm, in particular between 0.5 μm and 2.0 μm. A thermal protection of the, in particular, metallic base body is guaranteed by an oxide ceramic layer. Known ceramic structures are still susceptible to cyclical thermal stresses however and possibly tend to break apart and/or unbond. The resistance to alternating temperature loadings is clearly increased by a microstructure with ceramic columns of a diameter smaller than the diameter attained to date. A microstructure with ceramic columns with a mean column diameter of below 2.5 μm, in particular between 0.5 μm and 2.0 μm, has a high extension tolerance and a high cyclical load tolerance due to its alignment substantially perpendicular to the surface of the base body and to the fine columnar structure. In this way, differences in the thermal expansion coefficients of the in particular metallic base material and of the ceramic thermally insulating layer are well-balanced. Small column diameters such as these can be attained by a reactive gas flow sputtering method developed for high temperatures.

In an advantageous embodiment of the component, the oxide ceramic layer has columns with a column diameter in a region from 2.5 μm to 50 μm. An oxide ceramic layer with a fine column structure of below 2.5 μm mean column diameter is particularly suitable for a thermal protection of components of a gas turbine, which is exposed to cyclical temperature stresses of more than 1000° C. This includes, above all, gas turbine blades, and also components of the combustion chamber region of a gas turbine, in particular surfaces formed as heat shields. This is valid for stationary gas turbines for a use in power stations and also for aeroplane engines. It goes without saying that the thermally insulating layer in accordance with the invention is also suitable for other components exposed to high thermal loadings.

For this reason the component in accordance with an advantageous embodiment is in particular formed as a turbine blade, such as a guide vane or a rotor blade of a gas turbine, or as a component of a gas turbine pressurised by a hot gas, in particular a heat shield.

The object of the invention is satisfied in that a coating apparatus for coating a base body with an above-described layer system includes
a) a holding device (11) for positioning of the base body (1) in a chamber which can be closed in vacuum-tight manner,
b) a vacuum generating device for generating a vacuum in the chamber,
c) a source for making available layer material capable of being coated, with the source being formed as a hollow cathode arrangement (12) in particular, and
d) an additional separate heating apparatus (16) for the heating up of the base body (1),

The source is arranged in such a manner that layer material can be transported from the source to the component by means of a flow of inert gas. The object directed to a coating apparatus for the manufacture of a layer system on a base body is thus satisfied by an apparatus which includes a holding device for positioning of the base body in a vacuum chamber. A source is located in this vacuum chamber, such as, for example a hollow cathode through which an inert gas can flow. This cathode arrangement includes a cathode material and an anode, a gas outlet opening facing towards the holding device and also a gas inlet opening for inert gas and an additional, separate heating apparatus for heating the base body. The inert gas flowing into the cathode arrangement, such as argon, for example, is ionised there. The inert gas atoms impact on the surface of the cathode, by which means the cathode material is sputtered. The sputtered cathode material leaves the cathode arrangement in the direction of the base body or substrate together with the inert gas. Between leaving the cathode arrangement and striking the substrate, the flow of inert gas can be brought into contact with a flow of oxygen, so that the sputtered cathode material is oxidised in the flow or on striking the base body. An oxidant supply is provided in the apparatus outside the hollow cathode, in particular for the oxidation of the zirconium and if necessary of the added yttrium, through which the oxygen can be supplied in corresponding amounts. The sputtered zirconium and yttrium particles which are present as metal ions, metal atoms and/or metal clusters are transported out of the hollow cathode arrangement with the gas flow of the inert gas, in particular of the argon. These are completely oxidised in an adjusted oxygen reaction atmosphere outside of the hollow cathode. This takes place by means of a supply of oxygen through the oxidant supply in such a manner that, in conjunction with the flow of inert gas, penetration of the oxygen into the hollow cathode is largely avoided. The oxidised metal particles precipitate on the base body as a metal oxide ceramic thermally insulating layer. The oxidation can also take place directly after the precipitation on the surface of the base body. In an advantageous embodiment the cathode arrangement is formed as a hollow cathode arrangement, wherein a hollow body serves as a carrier for the cathode material applied in the interior of the hollow body. In a further embodiment the cathode arrangement includes at least one plate-shaped element, which comprises cathode material or is applied onto the cathode material.

In an advantageous embodiment of the coating apparatus the cathode arrangement can be flowed through by an inert gas. The cathode arrangement contains a cathode material, in particular an alloy made of zirconium, which can, in particular, contain a stabiliser metal such as yttrium, wherein the proportion of the stabiliser metal is determined in such a way that the proportion of the stabiliser metal oxide in the oxide ceramic layer can be adjusted to a range from 3% to 12%, in particular to a range from 3% to 8% by weight of the proportion of the zirconium oxide. An oxidant supply is provided for an oxidation of the cathode material outside the cathode arrangement. The source includes an anode, a gas outlet aperture facing towards the holding device and also a gas inlet aperture for inert gas. In the cathode arrangement, which is designed as a hollow body, in particular with a circular or with a rectangular cross-section, a glow discharge is produced by the creation of a direct voltage between the cathode and the anode. The anode can for example, be designed to be bar-shaped and be arranged in the cathode, or outside, in particular as a housing enclosing the cathode. In either case, due to a plasma arising in the cathode, such a large voltage drop is present between the plasma and the cathode that a continuous ionisation is sustained. In this way inert gas entering through the gas inlet aperture is ionised inside the hollow cathode. The ionised inert gas atoms strike on the metal surfaces of the hollow cathodes which have been connected to be cathodic, quasi an ion bombardment, and lead to an at least partial sputtering of the metal surfaces. The cathode material preferably comprises an alloy made of zirconium, through which zirconium atoms or zirconium atom clusters are struck out of the cathode material. In accordance with a desired stabilising of the subsequently oxidised zirconium deposited on the base body, a stabiliser metal such as yttrium is mixed with the cathode material or alloyed with it. The cathode material accordingly has a pre-determined surface or volume ratio of metallic zirconium and yttrium.

In an advantageous embodiment of the coating apparatus the cathode material contains an alloy of zirconium, in particular with a stabiliser metal, such as yttrium, with the proportion of the stabiliser metal being determined in such a way that in the oxide ceramic layer the proportion of the stabilising metal oxide is adjustable to a range of 3.0% to 12.0%, in particular to a range of 3.0% to 8.0% by weight of the proportion of the zirconium oxide. An oxidant supply can be provided outside the cathode arrangement for the oxidation of the zirconium.

In an advantageous embodiment of the coating apparatus for production of the cover layer, a cathode material is used in particular with a composition which is adjusted to the composition of the cover layer. In accordance with a first advantageous embodiment the cathode material contains a lanthanide, in particular gadolinium and/or lanthanum, and or zirconium, in particular with a stabilising metal, such as yttrium, with the ratio of the proportions being determined in such a way that the composition of a pyrochlorine or of a perovskite can be set.

In accordance with a second advantageous embodiment, the cathode material contains a lanthanide, in particular gadolinium and/or lanthanum, and or zirconium, in particular with a stabilising metal, such as yttrium, with the ratio of the proportions being determined in such a way that the composition of a pyrochlorine or of a perovskite with additions of a stabilising oxide, in particular Y₂O₃ can be set in the oxide ceramic cover layer.

The cathode material can either be applied in layers on the electrode or electrodes so that with the cathode material of a cathode one or a plurality of layers can be produced on the component, in particular the oxide ceramic layer, and also the cover layer and/or the graded zirconium layer which can also act as an oxide ceramic cover layer.

Alternatively, a cathode with cathode material can each be used in accordance with one of the above-named embodiments. The cathode is then exchanged in the course of the coating procedure, so that cathodes are used with the suitable cathode material in each case for each layer or for different layer combinations.

In an advantageous embodiment of the coating apparatus the heating apparatus is designed for heating up the base body to over 800° C., in particular to about 950° C. to 1050° C. To achieve the desired columnar structure, a corresponding adjustment of the pressure inside the coating apparatus takes place and also of the temperature, above all of the temperature of the base body. This is heated to a temperature of over 800° C., in particular to about 950° C. to 1050° C. by means of a heating apparatus.

In an advantageous embodiment of the coating apparatus, a vacuum pump apparatus is provided for the production of a vacuum in a vacuum-tight closable chamber of below 1 mbar, in particular of 0.3 mbar to 0.9 mbar. A decoupling of the working atmosphere for the ionisation of the inert gas (plasma source) and of the component to be coated is achieved with the coating apparatus for carrying out of a high-speed gas flow sputtering method. Using this gas flow sputtering method very high deposition rates of up to 100 μm/h and above can be attained, which make the use of this method on an industrial scale possible. In comparison with conventional PVD methods, in particular the electron beam PVD method, other value ranges of the parameters, such as the pressure of the residual gas (vacuum pressure, required pump level of the vacuum system), working pressure and also the ratio of the reactive gas (oxygen) to the remaining working gases are given. The atmosphere at the component to be coated can be at a residual gas pressure of 10⁻³ mbar for carrying out the method, with the upper limit of the residual pressure being of the order of magnitude of 10⁻² mbar. The working pressure at the component can be of the order of magnitude of between 0.2 and 0.9 mbar, in particular in the region of the main chamber of the coating apparatus. The ratio of the reactive gas (oxygen) to the ionised inert gas, in particular argon, which under the present conditions is present as plasma gas, can be in the range of 0.01 to 0.04. The atmosphere of the plasma source is substantially decoupled from the atmosphere of the component and has a residual gas pressure of the order of magnitude of the residual gas pressure at the component. The working pressure of the flow of gas can be about 0.02 mbar higher than the working pressure at the component. The working pressure at the component, i.e. in the main chamber of the coating system is consequently determined by means of the flow of gas out of the source. Consequently, an overpressure is present in the cathode arrangement in comparison with the main chamber. The proportion of residual gas, in particular oxygen, to the ionised inert gas (plasma gas) is preferably below 1%. In this way the ionisation source, in the above-described embodiment the hollow cathode arrangement, can be driven in direct voltage operation, since no oxidation of the coating source (hollow cathode) takes place with an instable operating state. In this way, the occurrence of a glow discharge is avoided and also the production of light arc plasmas due to an oxidation of the cathode material. In comparison with known apparatus for the carrying out of PVD methods, in particular an electron beam PVD method, a considerably higher residual pressure is thus possible, which results in a simplified and more economical vacuum system. The residual gas pressure in the known plants for attaining a columnar thermal insulating layer is in the range of 10⁻⁶ to 10⁻⁵ mbar. In the conventional process the working pressure is in the range of 10⁻³ to 10⁻² mbar with a technically meaningful upper limit smaller than 0.1 mbar and thus clearly below the working pressure possible in the reactive gas sputtering method. Moreover, in the known PVD methods, a high ratio of reactive gas (oxygen) to further working gases, such as argon, helium, etc. of 10:1 or higher, is necessary. In the apparatus in accordance with the invention and the method in accordance with the invention, a considerably lower ratio is needed, so that the supply devices for working gas and reactive gas can also be implemented considerably more simply and cheaply. In the known PVD methods, the coating source is in the main chamber without decoupling moreover, and is thus exposed to an oxidation without protection. The apparatus in accordance with the invention can thus be run without high frequency generators or real time regulated direct voltage generators. In this connection the heating apparatus is preferably formed in such a manner that a uniform heating, in particular volume heating of the base body is present. Even at places on the base body with a high mass concentration and large partial volume, a uniform germinating temperature is reached for the entire base body. The vacuum (working pressure) inside the coating apparatus is preferably below 1 mbar, in particular in the range between 0.3 mbar to 0.9 mbar, such as, for example, at 0.5 mbar. A vacuum pump apparatus is provided to set the desired vacuum, which can have a simple design, a Roots pump type for example. In comparison with the conventional electron beam PVD method, in which a rotary gate roughing pump and also a diffusion pump are to be provided to reach a high vacuum, the vacuum pump apparatus of the gas flow sputtering method can be made considerably simpler.

In an advantageous embodiment of the coating apparatus, the holding device is movable, in particular rotatably journalled, so that a continual to and fro movement and/or rotation of the base body is provided relative to the gas outlet aperture. The coating apparatus of the component is distinguished in particular by a plurality of sources being positioned about the rotational axis of the component, such as for example a turbine blade, which are protected from contamination by a shutter or a flow of gas without a plasma, and in which a plasma can be alternately triggered. It is naturally, in principle, also possible to attain one of the layers as a mix though the simultaneous coating from a plurality of sources. Alternatively, a charging between discreet vacuum chambers each having one source can naturally also take place. This variant is conceivable if the entire layer system, in particular including the bond promoting layer, can be formed as a metallic bondcoat layer, should be produced in a coating apparatus and if, for contamination reasons, a strict separation should take place between vacuum operation for layers with metallic content and reactive operation in a vacuum with oxygen supply. The metallic bondcoat layer can consist of the families of the MCrAlY, NiAl's, PtNiAl's, TiAl's and also combinations of these, however a direct coating of the ceramics on suitable superalloys can also take place. The reactive formation of the TGO (thermally grown oxide), such as is known from EB-PVD thermally insulating layers, the so-called TBC layers (thermal barrier coating) can be provided. The holding device is formed for a movement of the base body in relation to the gas outlet aperture in order to achieve as uniform a coating of the component as possible, in particular of a gas turbine blade. The holding device preferably includes a rotatating mechanism through which a continuous rotation of the component about its longitudinal axis takes place.

The object is thus satisfied in that a method for the coating of the base body under vacuum conditions with the above described layer system is used, in which an inert gas is ionised in a substantially oxygen-free atmosphere, the ionised inert gas is brought into contact with a cathode arrangement and there ejects from a cathode material, in particular from a metallic and/or ceramic cathode material, atoms and/or atom groups, whereupon the atoms and/or atom groups released from the cathode material are carried along with the inert gas in the direction of the base body (1), and to which oxygen is added before reaching the base body, so that a metal oxide and/or a oxide ceramic compound forms, which is deposited on the base body, or a metallic and/or ceramic compound is deposited on the base body or a metallic or a ceramic compound is deposited and is oxidised on the base body to a metal oxide or to an oxide ceramic compound by means of impinging oxygen, wherein the base body is heated up to a predetermined nucleation temperature of over 800° C., in particular in a range between 950° C. and 1050° C.

In the just described method for the coating of a base body under vacuum with a thermally insulating layer, an inert gas is ionised in a substantially oxygen-free atmosphere. This takes place, for example, by the inert gas being fed through a hollow cathode and ionised in this. The ionised atoms of the inert gas eliminate metal atoms and/or metal clusters out of a metallic cathode material, which are transported out of the hollow cathode with the inert gas and are oxidised to a metal oxide with oxygen outside the hollow cathode. It is likewise possible that metal is deposited on the base body and is oxidised there by means of impinging oxygen. The metal oxide is deposited on the base body, which is heated with a separate heating apparatus to a pre-determined nucleation and condensation temperature. In this way a thermally insulating layer, which has a fine columnar microstructure is manufactured on the base body from a metal oxide, wherein the mean column diameter can be below 2.5 μm, in particular can lie in a range between 0.5 μm to 2.0 μm. This thermally insulating layer has a particularly good resistance to thermomechanical alternating loads, such as is particularly advantageous in parts of a gas turbine plant loaded with a hot gas, such as turbine blades and insulating components.

In contrast to known electron beam PVD methods, a pure metal or an alloy of a main metal and at least one stabiliser metal is used as cathode material for the manufacture of the oxide ceramic layer. An alloy made of zirconium with yttrium is preferably particularly suitable for this, with the yttrium being added to the zirconium in such an amount and distribution that a thermally insulating layer of zirconium oxide partially stabilised with yttrium oxide arises. It goes without saying that other metals are also suitable as cathode material, which lead to a thermally highly-resistant metal oxide, such as magnesium zirconium oxide spinel. The use of a metallic cathode in place of a body made of metallic oxide, such as is used in the known electron beam PVD method, for example, has the advantage that the manufactured thermally insulating layer is substantially more finely structured. Furthermore, the occurrence of layer defects is avoided by a fully reactive oxidation process of the metallic sputtering materials released from the cathode material, which can arise in the electron beam PVD method due to defects in the ceramic body, such as inhomogeneous porosity or foreign body influences. Moreover, in comparison with a ceramic body, the cathode material can be manufactured more simply and with the highest purity.

The connection of the thermally insulating layer of metal oxide takes place via the formation of a homogeneously growing aluminium oxide reaction layer, (promoting layer) between the thermally insulating layer and a bonding layer made of a metal alloy of the kind MCrAlY, for example. The reactive gas sputtering method using a hollow cathode arrangement flowed through by an inert gas, has the advantage, moreover, that it can be carried out in a relatively coarse vacuum with sufficient deposition of metal oxides on the base body. In comparison with the known electron beam PVD methods with complicated electron beam deflection and focussing functions, the described method is distinguished by a simple regulation or control of the process factors, such as germinating temperature, vacuum pressure, oxygen partial pressure, volume flow of the inert gas, power of the hollow cathode discharge. The calculation of the process factors necessary to reach a structure with a mean column diameter of below 2.5 μm takes place with the help of the Thornton diagram for PVD formation of the layer structure, which is described, for example, in the Journal of Vacuum Science Technology, Vol. 11, 1974, pages 666 to 670 by J. A. Thornton. The formation of the layer structure in dependence on the substrate temperature, the vacuum chamber gas pressure and the layer energy content for the activation of the change of positional change processes is described in this. The anode either does not wear or wears substantially more slowly than the cathode material, since if arranged in the region of the gas inlet, it is not exposed to any coating or oxidation. Wear parts such as the anode or the cathode material can be kept small, in particular since the anode is arranged inside the hollow cathode, and thus is not exposed to a direct bombardment by electrons or ions. Moreover, the anode can be manufactured with a high degree of purity.

According to the above-described method, in particular a reactive gas flow sputtering method (HS-PVD) is used in combination with a vacuum arc vaporising method and/or a hollow cathode vaporising method and/or a low voltage arc vaporising method and/or an electron beam vaporising method and/or a PVD method, such as in particular the HF-PVD and/or DC-PCD method and/or an APS and/or LPPS and/or TF-LPPS and/or VPS is used.

The PVD (physical vapour deposition) method is a method in which layer material is applied to the substrate by means of deposition out of the vapour phase. In this arrangement, the production of the vapour takes place as is described in the book “Plasmabeschichtungsverfahren und Hartstoffschichten” (Engl.: Plasma coating methods and hard material layers”) by B. Rother and J. Vetter, Leipig, Dt. Verlag Für Grundstoffindustrie, 1992, in accordance with one of the following methods, which include the vacuum arc vaporisation method, the hollow cathode vaporisation method, the low voltage arc vaporisation method or an electron beam vaporisation method as vaporisation methods or by means of a DC or HF discharge as a reactive sputtering method, to which the preferably to be used HS-PVD method is to be counted. In the vacuum arc vaporisation method the reactive vaporisation takes place by means of a vacuum arc vaporiser. By means of the vacuum arc discharge in the vapour of the cathode material, the cathode material is ionised, enters the gas chamber and impinges there on the substrate to be coated. In the hollow cathode vaporiser (HKB) a powerful electron beam serves as an energy source for heating the cathode material, with a so-called quasi neutral plasma, i.e. a mixture of electrons and ions, each with the same charge density, being produced. This plasma is conducted onto a crucible anode, which contains coating material to be vaporised. The vaporised coating material is conducted from the anode onto the substrate. In a low voltage arc vaporiser, the discharge is conducted in a working gas with a burning voltage, which is below the ionisation voltage of the working gas. The cathode is formed as a glow cathode and acts as an electron emitter by means of thermo-emission along the discharge path. The charge carriers generated in this way can be used as ions in a sputtering method, just as they can be used as electrons for the vaporisation process. A further method for metal vapour generation for coatings is the electron beam vaporisation method, in which an electron beam is directed towards a vapour-emitting surface. The electron beam PVD method (EB-PVD), already mentioned several times, is understood by this.

In the sputtering method, the free particles are not produced out of the liquid phase, in contrast to the vaporising principle. The energy and the energy distribution of the sputtered particles accordingly differ from the corresponding values of vaporised particles. After leaving the solid material surface, sputtered atoms can possess 10 to 100 times more kinetic energy than vaporised particles. A substantial advantage of the solid material sputtering method in comparison with the vaporising principle is the possibility of sputtering alloys or also multi-component materials and depositing them again under certain preconditions as a layer. The DC sputtering method is particularly suitable for the sputtering of electrically conductible particles. The cathode serves a target and is simultaneously a negative electrode for maintaining the glow discharge. The substrate is arranged on the other electrode. The triode sputtering method can be regarded as a variant, in which the number of the ionised electrodes is increased, by using an additional electrode. By superimposing an electrical field with a magnetic field the ionisation probability increases, by which means one obtains a plasma generator independent of the target and the substrate. The material located on the target is sputtered by accelerating the ions of the plasma onto the target, in other words onto the source. By means of optimisation of the magnetic field guidance, one reaches the regime of the high-speed sputtering method (HS-PVD). The HF sputtering method is used for electrically non-conductive particles in the target, with HF standing for high frequency apparatus. A voltage potential is produced at the electrode by means of high frequency radiation, by exploiting the different mobility of electrons during the positive half wave relative to the ions during the negative half wave. The reactive sputtering method is a further variant, in which a reactive component is added to the inert gas.

A method combination of TF-LPPS (thin film low pressure plasma spraying) in accordance with EP-A-1260602 or WO-A-03087422 and the method described here for the production of multi-layer systems is also conceivable as an alternative. Using the LPPS thin film process a conventional LPPS plasma spraying method is modified method-wise. The coating material is injected in powder form into the plasma with a supply gas. A strong spatial extension of the plasma leads to a “defocusing” of the powder beam. In this arrangement the powder is dispersed to a cloud and melted and also partially or completely vaporised, due to a high enthalpy of the plasma. The coating material reaches a widely extended surface of the substrate in uniformly distributed form. A thin layer is deposited, the layer thickness of which is less than 10 μm and which forms a thick covering, thanks to the uniform distribution. By means of a multiple application of thin layers a thicker coating can be intentionally manufactured with special characteristics.

A coating of this kind can be used as a functional layer. A functional layer, which as a rule includes various part layers, can be applied on a base body, which forms the substrate. For example, the blades for gas turbines (stationary gas turbines or aircraft engines) which are operated at high process temperatures, are coated with a first one or multiple layer part layer, so that the substrate becomes resistant to hot gas corrosion. A second coating, applied to the first part layer—made of ceramic material—forms a thermally insulating layer. A method for producing a layer system of a thermally insulating layer system of this kind is described in EP-A-1 260 602, in which a plurality of individual layers (barrier layer, protective layer, thermally insulating layer and/or smoothing layer) can be applied by a changing adjustment of controllable process parameters in one operating cycle. The process parameters are the pressure and also the enthalpy of the plasma, the composition of the process gas and the composition and also form of application of the coating material.

The component, the apparatus and the method for the manufacture of the layer system on a base body will be described further with the help of the embodiments illustrated with the help of the drawings, which show:

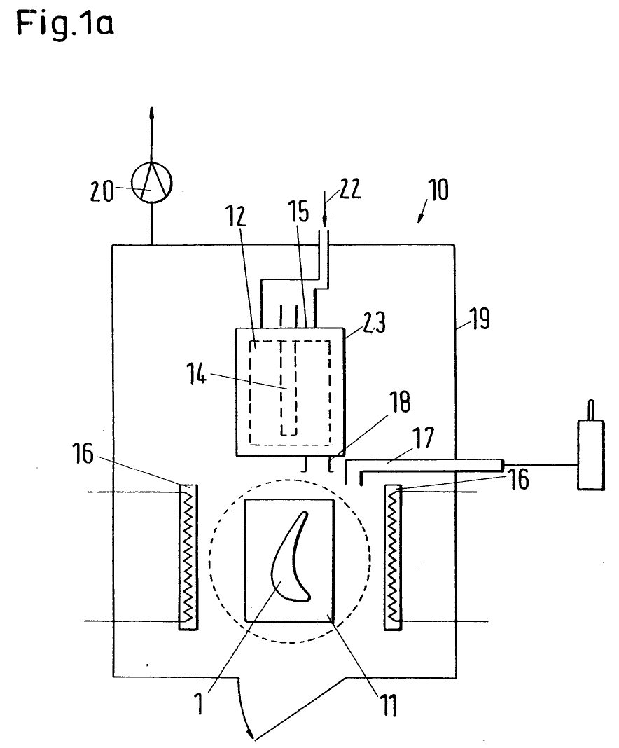

FIG. 1a a component arranged in an apparatus for coating with a thermally insulating layer in a view from above,

FIG. 1b a component arranged in an apparatus for coating with a thermally insulating layer in a side view,

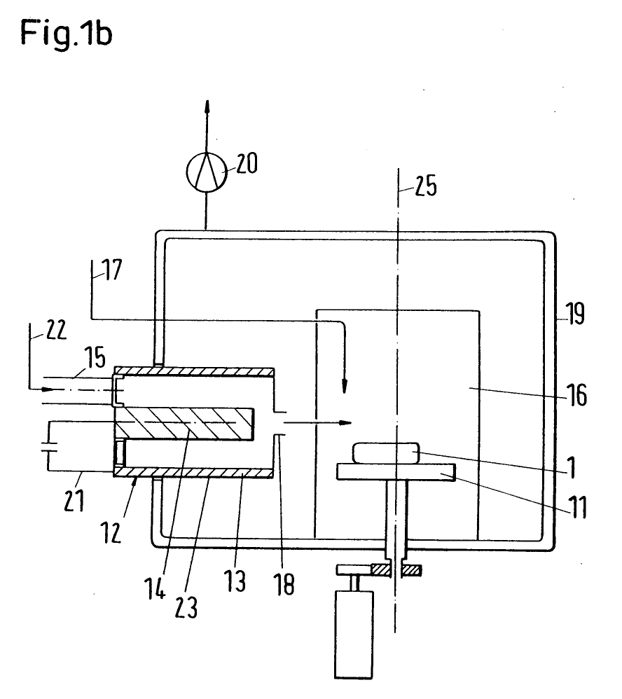

FIG. 2 a longitudinal section through the component in accordance with a first embodiment,

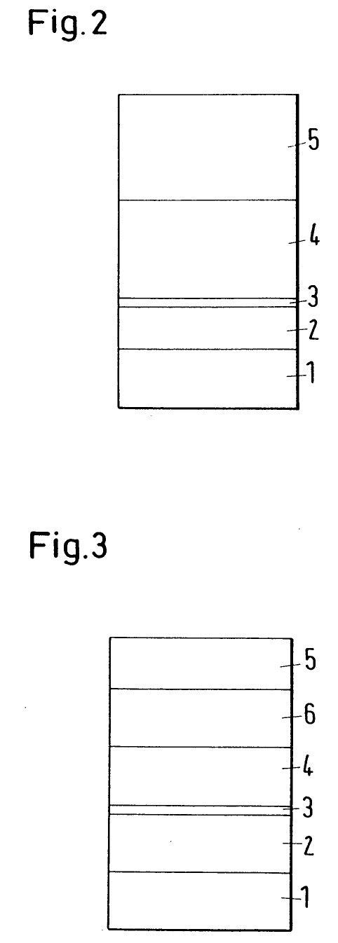

FIG. 3 a longitudinal section through the component in accordance with a further embodiment.

A principal layout of a coating apparatus 15 for the carrying out of a reactive gas flow sputtering method is shown in FIG. 1 schematically and not to scale. The coating apparatus 15 has a chamber 19, in which a vacuum of below 1 mbar, in particular approximately 0.5 mbar can be produced by means of a vacuum pumping apparatus 20. A hollow cathode arrangement 12 of circular cylindrical cross-section is arranged inside the chamber 19. A plurality of such cylindrical hollow cathodes or a linear hollow cathode with a rectangular cross-section, which is/are aligned along a longitudinal axis, can be used for the coating of large components. A bar-shaped anode 14 is arranged inside the hollow cathode 12, which is connected to the hollow cathode 12 via a direct voltage supply 21. The direct voltage supply 21 produces a direct voltage from 400 V to 800 V for example, which leads to a discharge current of approximately 2 A. The hollow cathode 12 has a cathode material 13, which is formed as a hollow cylinder or for example is made of individual plates filling the interior wall of the hollow cathode arrangement 12. The hollow cathode 12 has an exterior housing with a gas inlet aperture 15, which is connected to a not-illustrated gas supply, via which an inert gas 22, in particular argon, is fed into the hollow cathode 12. The exterior housing 23 serves to guide the flow of inert gas, to stop reactive gas from entering into the hollow cathode 12 and to screen surfaces at cathode potential, which are not to be sputtered, in particular not illustrated cooling plates of the cathode material 13. The hollow cathode 12 has a gas outlet aperture 18 lying opposite the gas inlet aperture 15, out of which the inert gas 22 flows after flowing through the region between the cathode material 13 and the anode 14. An oxidant supply 17 is arranged with a mouth region geodetically above the gas outlet opening 18, through which oxygen can be fed into the housing 23. Geodetically above the oxidant supply 17 a component, i.e. the base body 1, in particular a gas turbine blade, is held in a holding device 11. The holding device 11 is electrically connectable to the hollow cathode 12 via an additional voltage supply. A direct voltage which can be applied between the hollow cathode 12 and the holding device 11, i.e. the component 1 effects a surface cleaning of the component 1 by means of ionised inert gas atoms. The holding device 11 preferably has a drive apparatus, which is not illustrated in more detail, by means of which a continual rotation of the component 1 about its longitudinal axis takes place. Geodetically above the component 1, a heating apparatus 16 is arranged for heating the component via heat radiation and/or convection. The heating apparatus 16 can, of course, also be arranged at the same geodetic level beside the component 1, depending on the requirement. All configuration details can likewise be arranged in an inverted geodetic arrangement or in a horizontal arrangement.

For the application of a layer system, which is illustrated in FIG. 2 or FIG. 3, the component 1 is preferably heated to a temperature of over 800° C. The inert gas 22 is fed through the gas inlet aperture 15 into the hollow gas cathode 12. This is ionised in the form of a glow discharge due to the voltage difference prevailing in the hollow cathode 12, with the ionised gas atoms impinging on the cathode material 13. This is preferably a pure metal such as zirconium, which is mixed with stabilising metal, for example yttrium in a predetermined volume distribution. Metal atoms and/or metal clusters are released out of the cathode material 13 by the ionised inert gas atoms and are transported in the flow of inert gas 22 in the direction of the component 1. A complete oxidation of the metal atoms, especially to zirconium oxide and yttrium oxide, takes place by means of the oxygen fed via the oxidant supply 17. When the connection path to the component 1 is open, these precipitate onto the base body 2 of the component 1 in the form of a partially stabilised metal oxide ceramic thermally insulating layer 4. A uniform coating of the component 1 takes place by means of a rotation of the component 1 about its longitudinal axis 25. A thermally stable chemical bond of the metal oxide onto the base body 1 takes place by means of a metallic bond promoting layer 2 applied to the base body 1 and made of one of the aforementioned materials and by means of a TGO layer 2 of one of the aforementioned materials grown on it.

The deposition of the metal oxide takes place in the form of the thermally insulating layer with a finely structured columnar structure. The formed ceramic columns are predominantly normally aligned to the surface of the base body 1, and have a column diameter of, on average, below 5 μm, in particular, as could be shown with the help of experiments, between 0.5 μm and 3.0 μm. A particularly high resistance of the thermally insulating layer 4 to thermally alternating loading, with differences in temperature of up to over 1000° C., is achieved by means of this finely structured column structure with a small column diameter.

A cover layer 5 follows the thermally insulating layer, which is formed as an oxide ceramic layer.

The invention is thus distinguished by the fact that a thermally stable thermally insulating layer is deposited on a metallic base body by a simply controllable and regulateable method. This thermally insulating layer, which is coupled onto the metallic base body in a thermo-mechanically stable manner via one or more intermediate layers, has a finely structured columnar structure with a mean column diameter below 5.0 μm. Above all, a high resistance of the thermally insulating layer to thermally alternating loads is achieved in this way, which is thus particularly suitable for use with thermally highly stressed components, such as components of a gas turbine plant exposed to a hot gas, in particular gas turbine blades and combustion chamber linings.

1. A component, including a base body (1), in particular a metallic base body, which includes at least one nickel and/or cobalt-based alloy, and also a layer system arranged directly on the base body (1), including a bond promoting layer (2) and also a thermally insulating layer arranged on the bond promoting layer (2), including a TGO layer (3), in particular a slow growing aluminium oxide layer and/or chrome oxide layer, and also at least one oxide ceramic layer (4), which is arranged directly on the TGO layer, and a cover layer (5) arranged on the oxide ceramic layer (4) and made of an A₂E₂O₇ pyrochlorine, wherein A preferably includes a lanthanide, in particular gadolinium and E is preferably zirconium, and also in particular lanthanum zirconate and/or a perovskite phase, characterised in that the layer thicknesses of the oxide ceramic layer (4) and the cover layer (5) together amount to between 50 μm and 2 mm, in particular together amount to between 100 μm and 500 μm.

2. A component in accordance with claim 1, wherein the oxide ceramic layer (4) includes a zirconium oxide layer, in particular a graded zirconium oxide layer (6) and/or contains a stabiliser, such as, in particular, yttrium oxide and/or zirconium oxide, hafnium oxide or a mixed oxide of the two components which is present in a form partially stabilised by yttrium oxide.

3. A component in accordance with claim 1, in which the bond promoting layer (2) is formed as a metallic or intermetallic bond promoting layer, which includes in particular a M₁CrAlY alloy, wherein M₁ stands for at least one of the elements iron, cobalt, nickel, Cr stands for chrome, Al stands for aluminium, Y stands for yttrium and/or the bond promoting layer (2) contains at least one of the elements of the rare earths, hafnium, tantalum, silicon, and/or a metal aluminide, wherein the metal aluminide is NiAl, CoAl, TiAl, NiCrAl, CoCrAl, and also a PtM₂Al, wherein M₂ includes the elements Fe, Ni, Co, Cr or combinations of these, in particular PtNiAl, PtNiCrAl.

4. A component in accordance with claim 1, wherein a first oxide ceramic layer (4) is provided, which preferably has a thickness in the region of 5 to 50 μm, and also a first cover layer is provided which has preferably a thickness in the range from 5 to 50 μm, and also at least one further layer sequence is provided of a further oxide ceramic layer (4) and/or a cover layer (5).

5. A component in accordance with claim 1, wherein the oxide ceramic layer (4) has ceramic columns (5) with a column diameter of below 2.5 μm, in particular between 0.5 μm and 2.0 μm.

6. A component in accordance with claim 1, wherein the oxide ceramic layer (4) has ceramic columns (5) with a column diameter in a range from 2.5 μm to 50 μm.

7. A component in accordance with claim 1, which is formed in particular as a turbine blade, such as a guide vane or a rotor blade of a gas turbine, or as a component of a gas turbine acted on by a hot gas, in particular a heat shield.

8. A coating apparatus (10) for the coating of a base body (1) with a layer system in accordance with claim 1 including
a) a holding device (11) for positioning of the base body (1) in a closable chamber,
b) a vacuum generating device for generating a vacuum in the chamber,
c) at least one source for making available coatable layer material, wherein the source is formed as a cathode arrangement (12) in particular, and
d) an additional separate heating apparatus (16) for the heating up of the base body (1),
characterised in that the source is arranged and designed in such a manner that layer material can be transported from the source to the component by means of an inert gas flow.

9. A coating apparatus in accordance with claim 8, wherein the cathode arrangement (12) can be flowed through by an inert gas and wherein a cathode material (13) can be sputtered, with the cathode material containing an alloy made of zirconium, and also in particular a stabilising metal, such as yttrium for example, wherein the proportion of the stabilising metal is determined in such a way that in the oxide ceramic layer (4) the proportion of the stabilising metal oxide is adjustable to a range of 3.0% to 12.0%, in particular to a range of 3.0% to 8.0% by weight of the proportion of the zirconium oxide, wherein an oxidant supply (17) is provided for an oxidation of the sputtered cathode material outside the cathode arrangement (12), with the source including an anode (14), a gas outlet opening (18) facing towards the holding device (11) and also a gas inlet opening (15) for inert gas.

10. A coating apparatus (10) in accordance with claim 8, in which the cathode material (13) contains an alloy of zirconium, in particular with a stabilising metal, such as yttrium, wherein the proportion of the stabilising metal is determined in such a way that in the oxide ceramic layer (4) the proportion of the stabilising metal oxide is adjustable to a range from 3.0% to 12.0%, in particular to a range from 3.0% to 8.0% by weight of the proportion of the zirconium oxide and wherein an oxidant supply (17) is provided for an oxidation of the zirconium outside the hollow cathode arrangement (12).

11. A coating apparatus in accordance with claim 8, wherein the cathode material contains a lanthanide, in particular gadolinium and/or lanthanum, and or zirconium, wherein the ratio of the proportions is determined in such a way that the composition of a pyrochlorine and/or of a perovskite can be set in the oxide ceramic cover layer (5).

12. A coating apparatus (10) in accordance with claim 8, wherein the cathode material contains a lanthanide, in particular gadolinium and/or lanthanum, and or zirconium, in particular with a stabilising metal, such as yttrium, wherein the ratio of the proportions is determined in such a way that the composition of a pyrochlorine or of a perovskite with additions of a stabilising oxide, in particular Y₂O₃ can be set in the oxide ceramic cover layer (5).

13. A coating apparatus (10) in accordance with claim 8, in which the heating apparatus (16) is designed for heating up the base body (1) to over 800° C., in particular to about 950° C. to about 1050° C.

14. A coating apparatus (10) in accordance with claim 8, wherein a vacuum pump apparatus (20) is provided for the generation of a vacuum in a vacuum-sealed lockable chamber of below 1 mbar, in particular of 0.3 mbar to 0.9 mbar.

15. A coating apparatus (10) in accordance with claim 8, in which the holding device (11) is movably, in particularly rotatably supported, so that a continual to and fro movement and/or rotation of the base body (1) is made possible relative to the gas outlet opening (18).

16. A method for the coating of a base body (1) with a layer system in accordance with claim 1 under vacuum conditions, wherein an inert gas is ionised in a substantially oxygen-free atmosphere, the inert gas is brought into contact with a cathode material, wherein the ionised inert gas releases atoms and/or atom groups from a cathode material, in particular from a metallic and/or ceramic cathode material, whereupon the atoms and/or atom groups released from the cathode material are carried along with the inert gas in the direction of the base body (1) and a metallic and/or ceramic compound is deposited on the base body (1), with the base body (1) being heated up to a predetermined nucleation temperature of over 800° C., in particular in a range between 950° C. and 1050° C.

17. A method in accordance with claim 16, wherein oxygen is added to the atoms and/or atom groups before reaching the base body (1), so that a metal oxide and/or an oxide ceramic compound forms, which is deposited on the base body (1), or a metallic and/or ceramic compound is deposited on the base body (1) and is oxidised to a metal oxide or to an oxide ceramic compound on the base body by means of incident oxygen.

18. A method in accordance with claim 16, wherein, in particular, a reactive gas flow sputtering method and/or a reactive gas flow sputtering method in combination with a vacuum arc vaporising method and/or a hollow cathode vaporising method and/or a low voltage arc vaporising method and/or an electron beam vaporising method and/or a PVD method, such as in particular the HF-PVD and/or DC-PCD method and/or an APS and/or LPPS and/or TF-LPPS and/or VPS method is used.
